(19) United States
(12) Patent Application Publication
(10) Pub. No.: US 2022/0278185 A1
(43) Pub. Date: Sep. 1, 2022

(54) OLED MICRODISPLAY SYSTEM

(71) Applicant: Universal Display Corporation, Ewing, NJ (US)

(72) Inventors: Michael HACK, Carmel, CA (US); Michael Stuart WEAVER, Princeton, NJ (US); Zhaoqun ZHOU, Bridgewater, NJ (US)

(21) Appl. No.: 17/674,330

(22) Filed: Feb. 17, 2022

Related U.S. Application Data
(60) Provisional application No. 63/154,888, filed on Mar. 1, 2021.
(60) Provisional application No. 63/177,795, filed on Apr. 21, 2021.

(51) Int. Cl. H01L 27/32; H01L 25/04

(52) U.S. Cl. CPC H01L 27/3267; H01L 27/3209; H01L 27/3286; H01L 25/048

(57) ABSTRACT

Embodiments of the disclosed subject matter provide a display including a plurality of emissive surfaces, where each of the plurality of emissive surfaces has emissive devices that are deposited or attached in the same plane, with each of the plurality of emissive surfaces configured with independent scan and data drivers. The display may be configured to display an image that is a combination of light from the plurality of emissive surfaces, wherein each of the plurality of emissive surfaces renders an image that differs by at least one selected from the group consisting of: color resolution, fill-factor, viewing angle, and transparency. Embodiments also provide an augmented reality (AR), virtual reality (VR), or mixed reality (MR) system having a plurality of displays that each rendering an image based on the provided light of a different color spectrum, and one or more waveguides through which the light from the displays is combined.

### CROSS-REFERENCE TO RELATED APPLICATIONS

This application claims priority to U.S. Patent Application Ser. No. 63/154,888, filed Mar. 1, 2021, and to U.S. Patent Application Ser. No. 63/177,795, filed Apr. 21, 2021, the entire contents of each are incorporated herein by reference.

### FIELD

The present invention relates to devices including displays and/or microdisplays with increased resolution and brightness by using a plurality of emission surfaces, and devices and techniques including the same.

### BACKGROUND

Opto-electronic devices that make use of organic materials are becoming increasingly desirable for a number of reasons. Many of the materials used to make such devices are relatively inexpensive, so organic-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-S00 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 1, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, a device may be provided that includes a display having a plurality of emissive surfaces, where each of the plurality of emissive surfaces has emissive devices that are deposited or attached in the same plane, with each of the plurality of emissive surfaces configured with independent scan and data drivers. The display may be configured to display an image that is a combination of light from the plurality of emissive surfaces, where each of the plurality of emissive surfaces renders an image that differs by color resolution, fill-factor, viewing angle, and/or transparency.

The display of the device may be a microdisplay that has a diagonal measurement that is less than or equal to three inches. The display may be a microdisplay has a resolution that is greater than 1000 dots per inch (DPI) or 1000 pixels per inch (PPI).

The display of the device may be an organic light emitting device (OLED) display, a micro-OLED display, a light emitting device (LED) display, a micro-LED display, a quantum dot display, a quantum dot LED display, and/or a perovskite LED display. The emissive devices of the display of the device may be organic light emitting devices (OLEDs), light emitting devices (LEDs), perovskite LEDs, micro-LEDs, micro-OLEDs, and/or quantum dots.

A first emissive surface of the plurality of emissive surface of the device may be configured to emit blue light, and a second emissive surface of the plurality of emissive surfaces may be configured to emit green light and red light. The first emissive surface may be disposed on a transparent substrate, and the first emissive surface may include a plurality of planes of emissive materials that are stacked vertically and are configured to emit the blue light. The stacked arrangement of emissive materials may include at least one microcavity configured to emit the blue light.

The display of the device may include a plurality of emissive devices disposed in a stacked arrangement, where the emissive devices may be organic light emitting devices (OLEDs), light emitting devices (LEDs), perovskite LEDs, micro-LEDs, micro-OLEDs, and/or quantum dots.

A first emissive surface of the plurality of emissive surface of the device may be configured to emit blue light, and a second emissive surface of the plurality of emissive surfaces may be configured to emit yellow light. The display of the device may include color altering media configured to output green light or red light based on the blue light emitted from the first emissive surface, and/or the yellow light emitted from the second emissive surface.

The plurality of emissive surfaces of the device may include a plurality of pixels, where one or more pixels of the plurality of pixels that are configured to emit blue light have a lower resolution than pixels of other colors of the plurality of pixels.

The plurality of emissive surfaces may include a plurality of pixels, and the device may include a passive matrix drive or addressing system that is configured to drive at least one of the plurality of pixels that is configured to emit blue light. The device may include a first active matrix drive system that is configured to drive one or more pixels of the plurality of pixels that are configured to emit yellow light, one or more pixels of the plurality of pixels that are configured to emit green light, and/or one or more pixels of the plurality of pixels that are configured to emit red light. The device may include a second active matrix drive system that is configured to drive a portion of the plurality of pixels that are configured to emit blue light, where the second active matrix drive system drives the portion of the plurality of pixels in a different region than the passive matrix drive system. The passive matrix drive system of the device may include a thin film transistor (TFT) per pixel of a plurality of sub-pixels that are configured to emit blue light.

The plurality of emissive surfaces of device may include a first emissive surface having a plurality of pixels configured to emit blue light. A second emissive surface may include a plurality of pixels configured to emit yellow light, green light, and/or red light. The device may include a dichroic filter disposed between the first emissive surface and the second emissive surface configured to pass the yellow light, the green light, and/or red light through the dichroic filter, and/or be configured to reflect the blue light.

One of the plurality of emissive surfaces of the device may include a backplane from a growth substrate.

According to an embodiment, a device may include an augmented reality (AR), virtual reality (VR), or mixed reality (MR) system having a plurality of displays, with each of the plurality of displays rendering an image based on the provided light of a different color spectrum. The device may include one or more waveguides through which light from the plurality of displays is combined and configured to be viewable by a user.

Each of the plurality of displays of the device may be a microdisplay that has a diagonal measurement that is less than or equal to three inches. Each of the plurality of displays of the device may be a microdisplay that has a resolution that is greater than 1000 dots per inch (DPI) or 1000 pixels per inch (PPI).

The display of the device may be an organic light emitting device (OLED) display, a micro-OLED display, a light emitting device (LED) display, a micro-LED display, a quantum dot display, a quantum dot LED display, and/or a perovskite LED display.

The plurality of displays of the device may include a first display configured to emit blue light, and a second display configured to emit red light and green light. The first display of the device may have a lower resolution that the second display. The second display may include an unpatterned mixture of quantum dots, OLEDs, micro-LEDs, and/or perovskite LEDs that may be configured to emit red or green light that are disposed over a micro light emitting device (micro-LED), quantum dot LED, perovskite LED, and/or a micro organic light emitting device (micro-OLED) of the first display that may be configured to emit blue light. The second display may include a first layer configured to emit red light to a second layer to emit green light. The first layer and the second layer may have different thicknesses, and may be stacked on the first display.

The plurality of displays of the device may include a first display configured to emit blue light, a plurality quantum dots configured to absorb the emitted blue light and output yellow light, and/or a plurality of filters configured to convert the yellow light into red light and green light.

The one or more waveguides of the device may include a first waveguide configured to guide blue light, a second waveguide configured to guide green light, and/or a third waveguide configured to guide red light.

A consumer product may include the devices described above, and may be a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display less than 3 inches diagonal, a 3-D display, a virtual reality or augmented reality display, a vehicle, a video wall comprising multiple displays tiled together, a theater or stadium screen, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a two-plane display arrangement including an optional a dichroic filter according to an embodiment of the disclosed subject matter.

FIG. 4 shows an arrangement of two displays outputting light into each side of a stack of waveguides in a pair of AR (augmented reality) glasses according to an embodiment of the disclosed subject matter.

FIG. 5 shows a diagram of a semi-transparent (weak cavity) blue PHOLED (phosphorescent organic light emitting device) top emitting device structure, where a thickness of the hole transport layer (HTL) is 10 nm to 200 nm and a thickness of the capping layer (CPL) is from 30 nm to 200 nm, according to an embodiment of the disclosed subject matter.

FIG. 6 shows an EL (electroluminescence) spectrum of a BE (bottom emitting) PHOLED and simulated EL spectrum of a top emitting microcavity (TEMC) device according to an embodiment of the disclosed subject matter.

FIG. 7 shows the transmittance of simulated semi-transparent (weak cavity) TEMC PHOLEDs as function of wavelength according to an embodiment of the disclosed subject matter.

FIG. 8 shows the simulated reflectance of dichroic filters as function of wavelength, where SiO₂/Si₃N₄ and SiO₂/AlGaAs 6 dyad stacks are demonstrated for comparing transmittance response at visible spectrum according to an embodiment of the disclosed subject matter.

FIG. 9 shows a diagram of a blue emissive weak cavity device disposed on a dichroic filter substrate, where the thickness of HTL is from 10 nm to 200 nm and the thickness of the CPL is from 30 nm to 200 nm according to an embodiment of the disclosed subject matter.

FIG. 10 shows simulated TEMC spectra on devices disposed on dichroic filters according to embodiments of the disclosed subject matter.

FIG. 11 shows simulated TEMC electroluminescence spectra with 1931 CIEy˜0.12 and with different 1931 CIEx on devices disposed on dichroic filters according to embodiments of the disclosed subject matter.

FIG. 12 shows the transmittance of simulated PHOLEDs with and without a dichroic stack configured at 1931 CIEy˜0.058 according to embodiments of the disclosed subject matter.

FIG. 13 shows the transmittance of simulated PHOLEDs with and without a dichroic stack configured at 1931 CIEy˜0.12 according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

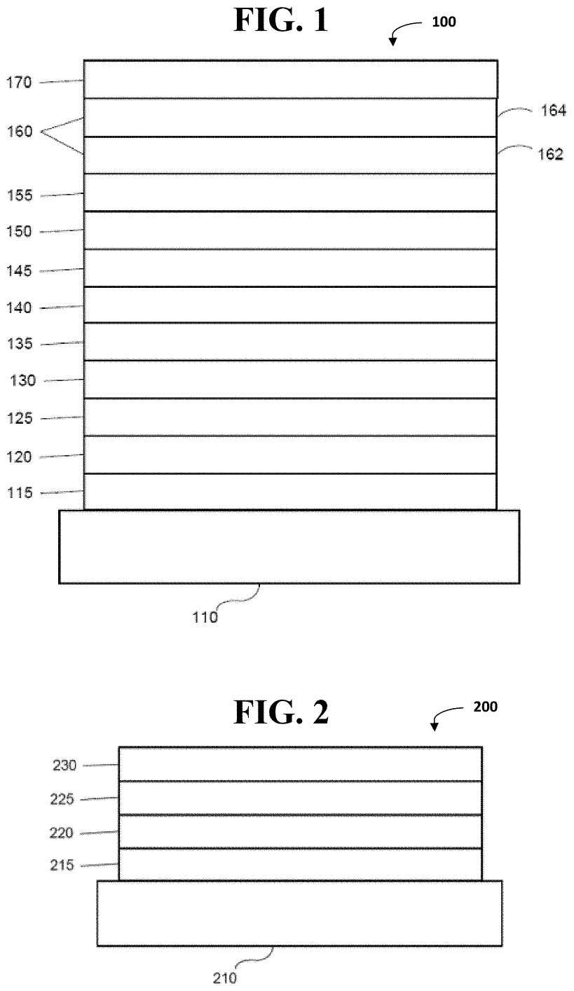

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light, which may be altered by another layer such as a color filter or other color altering layer that does not itself emit an initial light within the device, but may re-emit altered light of a different spectra content based upon initial light emitted by the emissive layer.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments, the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 3 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Displays such as micro-OLED displays are increasingly being used in devices. Achieving high brightness that is greater than a predetermined brightness and high resolution that is greater than a predetermined resolution for a display while having an operational lifetime that is greater than a predetermined operational lifetime is challenging. Such features may be especially difficult to achieve for a transparent display where an active area is reduced to allow for transparent inactive regions. Embodiments of the disclosed subject matter provide a device architecture that enables displays, such as OLED microdisplays and/or other displays as disclosed herein, to have a brightness and operational lifetimes that are greater than predetermined brightness and operation lifetime amounts by using two or more emissive surfaces. Each emissive surface may be refer to an emissive plane, and the different emissive surfaces are in different planes. For example, the emissive surfaces may both have AMOLED (active matrix organic light emitting device) emission. One of the emissive surfaces may have AMOLED emission, and one emissive surface may have PMOLED (passive matrix organic light emitting device) emission. One of the emissive surfaces may produce yellow (and/or red and green) images, and another emissive surface may produce blue images. These images may be combined to form a full color transparent display, or a full color non-transparent display showing a single full color image that is a combination of the blue and yellow (and/or red and green) images. Embodiments of the disclosed subject matter may include two substrates to reduce and/or eliminate patterning requirements for large area substrates.

Competing requirements of transparency and long operational lifetimes may use multiple emissive layers to achieve brightness and lifetime values that are greater than predetermined amounts, especially with pixels designed with reduced fill-factor. While it is possible that stacked structures may achieve this, the use of emission from emissive surfaces on two different substrates may provide additional benefits, as the characteristics of each substrate and emissive surfaces may be optimized. Each emissive surface may emit the same image information, but each emissive surface may provide a different color portion of the complete image. That is, when the images of each of the emissive surfaces are combined, a full color image may be formed.

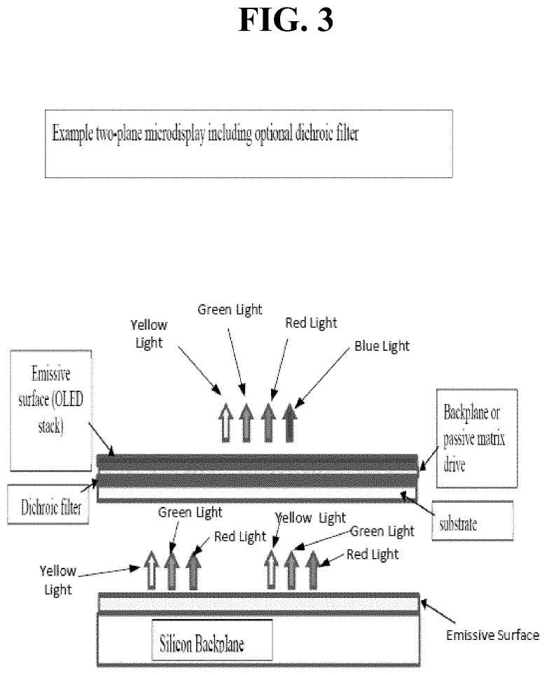

As shown in FIG. 3, a silicon substrate may include active-matrix circuitry for emission of the sub-pixels (e.g., OLED subpixels or the like) that may be deposited over the backplane. The OLED deposition may be unpatterned yellow (at the pixel level) or else patterned green and red sub-pixels. For an unpatterned yellow OLED deposition, color altering media may be used to make green sub-pixels and red sub-pixels, and this part of the display may be RG (i.e., emit red and green light) or RGY (i.e., emit red, green, and yellow light) to render RGB or RGBY when combined with a blue emissive surface that may be in an emissive plane and/or disposed on a substrate.

A second emissive surface may be in a plane and/or formed on a transparent substrate. The substrate may be glass, as it is rigid and may support high resolution pixels (e.g., that have a resolution that is greater than a predetermined resolution). This emissive surface may be an unpatterned blue organic layer. This second emissive surface may have a high transparency (e.g., a transparency that is greater than a predetermined amount) to reduce optical losses of light emitted from the first emissive surface (e.g., that may emit yellow light, and/or emit red and/or green light) through the blue emissive surface and/or substrate. The first emissive surface and the second emissive surface may be in different planes. Due to the human eye having lower resolution for blue light, the resolution of the blue emissive surface may be ¼ or perhaps even 1/16 of the yellow emissive surface. For example, if the yellow emissive surface has 4K×2K pixels, then the blue emissive surface may have 1,000×500 pixels. If this device is driven from all four sides, it may be partitioned into 4 separate displays, each 500×250 pixels. This may make the device amenable to being driven as a passive matrix display with 500 data lines and 250 scan lines, as the dimensions may be small (around 1 cm to 5 cm) and electrical losses in the bus lines may be minimized. A conventional passive matrix OLED display uses patterned anode lines and patterned cathode lines to select individual pixels for emission. Cathode patterning may be difficult for high resolution devices (e.g., using cathode separators). An alternative approach may be to place a TFT (a thin film transistor, such as a one pass TFT) in each blue pixel so that conventional scan and data lines may be used to provide current drive to the OLED stack anode and there may be no need to pattern the cathode.

The top surface of the Y (and/or RG) emissive surface and substrate characteristics of the blue (B) emissive surface, such as the refractive index and the like, may be selected to maximize in-coupling to from the RG(Y) emission into the substrate that includes the blue (B) emissive surface to minimize losses at this interface. An index-matching medium may be disposed between the top surface of the Y (and/or RG) emissive surface and the substrate of the blue (B) emissive surface to reduce optical losses at an interface. For example, the index matching medium may be included when two standalone devices are stacked together for cost-effective product integration.

An alternative approach may include providing a high-resolution backplane to the blue emissive plane (and so allow for high transparency) to form the active-matrix backplane on another substrate. Lift-off techniques may be used to transfer the backplane from this growth substrate to the blue emissive substrate to be used in this display.

In another embodiment, some of the blue emissive surface may be driven as an active matrix, and a portion of this emissive surface may be driven as a passive matrix. This may reduce the multiplexing requirements for the passive matrix drive (and/or associated electrical losses that may be caused by high instantaneous currents flowing through bus lines) while improving transparency by not requiring every pixel to have multiple TFT active matrix pixel circuits.

To meet the saturation of DCI-P3 or other color gamuts, a blue emissive OLED stack may be disposed in a microcavity to reduce the “green” (i.e., the longer wavelength) emission in the spectrum tail. For the second emissive surface (e.g., the blue emissive surface) that may include transparent OLEDs, there may be at least two ways to achieve a blue emissive cavity (e.g., a weak cavity producing an emission that is less than a predetermined amount) to suppress the green tail emission. One way may be to use a weakly reflecting anode and/or cathode on the blue emissive surface to provide a semi-transparent electrode that may support a weak cavity. Another way may be to place a dichroic filter on the second emissive surface (e.g., the blue emissive surface) to be transparent to red, green, and/or yellow light, but reflect blue light so as to provide a cavity for the blue pixels as shown, for example, in FIG. 3. The dichroic filter may be in contact with the first electrode in the blue emissive device. The approaches described above may also be combined, or other approaches used.

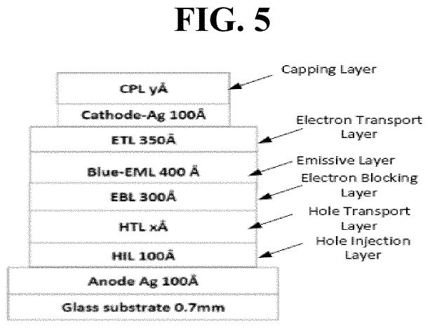

To demonstrate the emissive blue cavity (e.g., the weak cavity), a top emitting device may be used, as shown in the simulation of FIG. 5. Top and bottom semi-transparent electrodes of Ag at 10 nm thickness were used as in the top emitting (TE) device to simplify the optical simulation. In a real situation, low work-function Mg may be co-doped in the cathode Ag layer for electron injection purposes. The simulation results and device structure (both with and without a dichroic filter) of the disclosed subject matter may apply to semi-transparent Mg:Ag x % cathodes, where x % may be from 10% to 100%. The capping layer (CPL) on TE cathode may enhance emission efficiency. The thickness of the CPL may be adjusted in the simulation to accommodate maximal performance in the weak emissive blue cavity. As shown in FIG. 5, the capping layer (CPL) may have a thickness y, which may be 30 nm to 200 nm. The hole transport layer (HTL) may have a thickness x, which may be 10 nm to 200 nm.

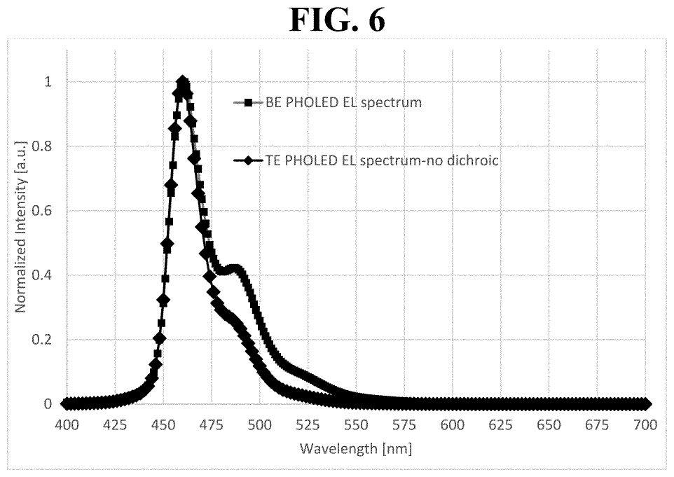

FIG. 6 shows the intrinsic spectrum of a phosphorescent blue dopant in bottom emitting (BE) device. The simulated spectrum in top emitting (TE) device using BE emission spectrum is demonstrated in FIG. 6. Due to the semi-transparent weak blue emissive cavity device and long wavelength emission (i.e., green tail emission) residing in the blue emissive cavity device, the spectrum of TE device may have a large proportion of blue-greenish emission compared to a predetermined emissive amount, which may reduce the color saturation in a display application. The efficacy of the weak blue emissive cavity may be reduced compared to a predetermined emissive amount.

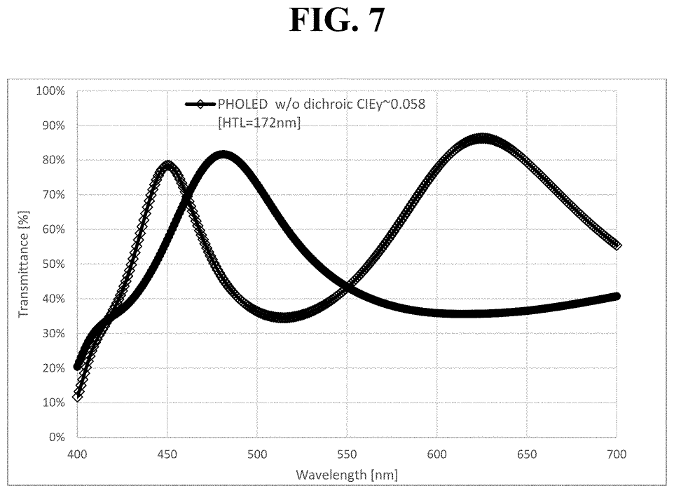

FIG. 7 shows the transmittance spectra of a PHOLED TE device at 2 example emission color points at 1931 CIEy˜0.058 and 1931 CIEy˜0.12, respectively. The disclosed subject matter is not limited to micro-displays, and embodiments disclosed throughout may be used in other displays. In micro-display applications, deep blue emission may be optional. Two color points in the TE devices were simulated to demonstrate the feasibility of adding a dichroic filter to weak blue emissive cavity device, as the blue saturation is enhanced, while the green and/or red emission or yellow emission may pass through. The semi-transparent blue stack may provide partial transmittance of green and red emission through the weak blue emissive cavity.

TABLE 1

| HTL/CPL thickness | | 1931 | | | | |
|---|---|---|---|---|---|---|
| [Top/Bottom | Dichroic | CIE | T % at | T % at | LE* | LE/1931 |
| Ag = 10 nm] | Stack | x, y | 535 nm | 625 nm | [cd/A] | CIEy |
| HTL = 172 nm; | none | 0.142, | 38% | 86% | 3.61 | 62 |
| CPL = 80 nm | | 0.058 | | | | |
| HTL = 15 nm; | SiO₂/Si3N₄/Glass | 0.140, | 56% | 74% | 3.90 | 67 |
| CPL = 60 nm | [135 nm @6 dyads] | 0.058 | | | | |
| HTL = 64 nm; | SiO₂/AlGaAs/Glass | 0.136, | 37% | 50% | 15.3 | 278 |
| CPL = 60 nm | [88 nm @6 dyads] | 0.055 | | | | |
| HTL = 189 nm; | SiO₂/AlGaAs/Glass | 0.133, | 36% | 63% | 12.7 | 231 |
| CPL = 60 nm | [88 nm @6 dyads] | 0.055 | | | | |

Table 1 shows simulation results (a top emitting microcavity (TEMC) performance target at 1931 CIEx˜0.055-0.058) on a top emitting (TE) device without a dichroic filter or stack, and a TE with a dichroic stack. * LE [cd/A], where LE is luminous efficiency, is optically simulated without considering triplet emission efficiency and dipole alignment. The calculated LE here is simplified for comparing performance enhancement between devices without with dichroic filter. T % may be percentage of transmittance at particular wavelengths (e.g., 535 nm, 625 nm, or the like).

As green and red emission may be partially transmissible through the weak blue emissive cavity, the efficiency of blue emissive cavity may be based on the design of the cavity. As shown in Table 1, the simulated luminance efficacy based on the blue TE device structure used in the FIG. 5 is 3.61 cd/A. The real luminance efficacy may be much higher, considering the triplet emission rate and horizontally aligned dipole moment that may boost device efficiency.

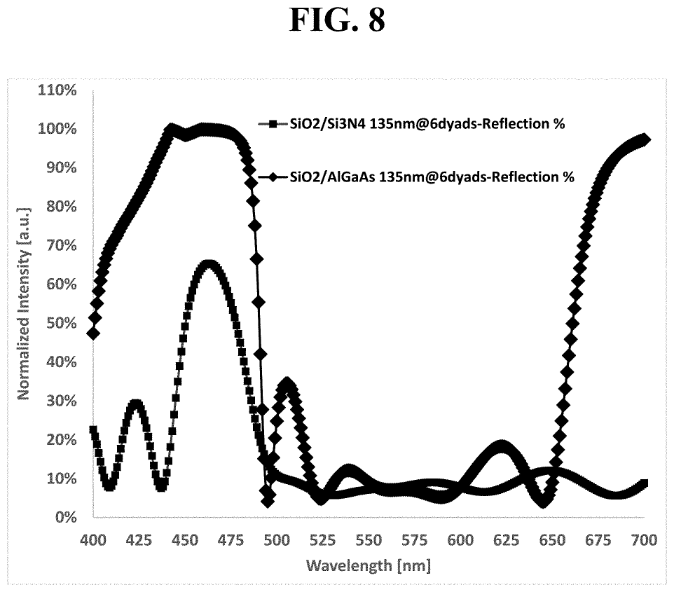

To improve blue color saturation and efficacy in the semi-transparent cavity stack, two different dichroic stacks may reflect blue light emission (e.g., peak emission of −460 nm) while minimizing the reflectance of green light (e.g., peak emission of −535 nm) and red light (e.g., peak emission of −625 nm) as shown in FIG. 8. The details of SiO₂/Si₃N₄ and SiO₂/AlGaAs dyad stack are shown in FIG. 8. The thickness of each layer in the dichroic stack may be 135 nm and 88 nm for SiO₂/Si₃N₄ and SiO₂/AlGaAs respectively. Due to the higher refractive index of AlGaAs versus Si₃N₄, higher reflectance at −460 nm in SiO₂/AlGaAs stack is demonstrated by the simulation shown FIG. 8. To maximize the blue light reflection and green and/or red or yellow light transmittance, the refractive index of a low index material in the dichroic should range between 1 to 2, while the refractive index of high index materials may range between 1.4 to 4.0 in the visible spectrum. In the dichroic stack, the delta of high n and low n may be greater than 1.

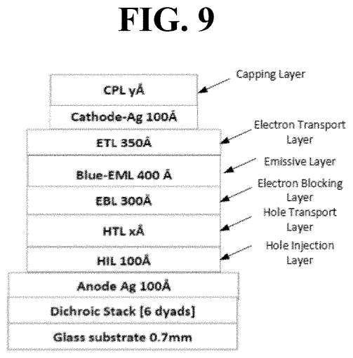

FIG. 9 shows a diagram of an example OLED stack with a dichroic filter. A glass substrate may be optional, so long as the dichroic filter is robust enough to serve as the substrate and/or to provide support to OLED. The dichroic filter may encapsulate the second OLED stack, on which green and/or red or yellow OLED devices may be disposed. As shown in FIG. 9, the capping layer (CPL) may have a thickness y, which may be 30 nm to 200 nm. The hole transport layer (HTL) may have a thickness x, which may be 10 nm to 200 nm.

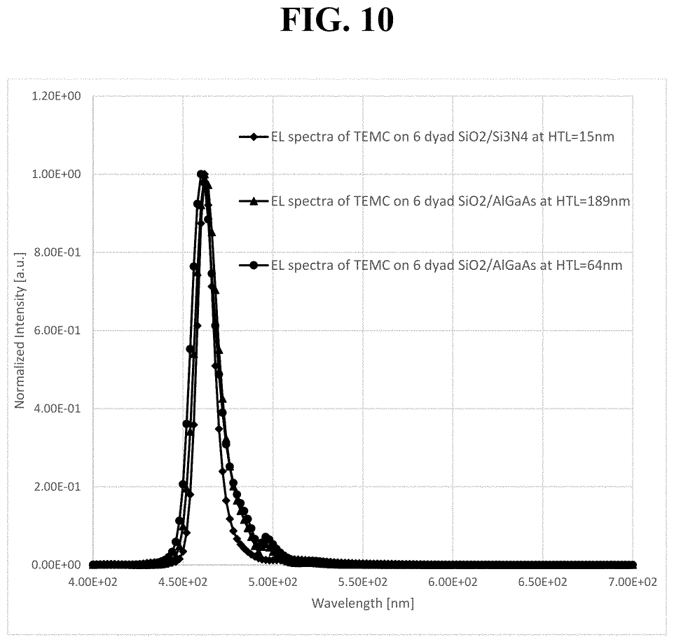

FIG. 10 shows simulated TEMC EL spectra at 1931 CIEy˜0.055-0.058 on SiO₂/Si₃N₄ and SiO₂/AlGaAs with a dichroic stack as a blue light reflector. Compared with spectra of TE devices without dichroic filter as shown in FIG. 6, the spectra of devices with dichroic filter show a narrower full width at half maximum (FWHM), which yield a blue emission with increased saturation.

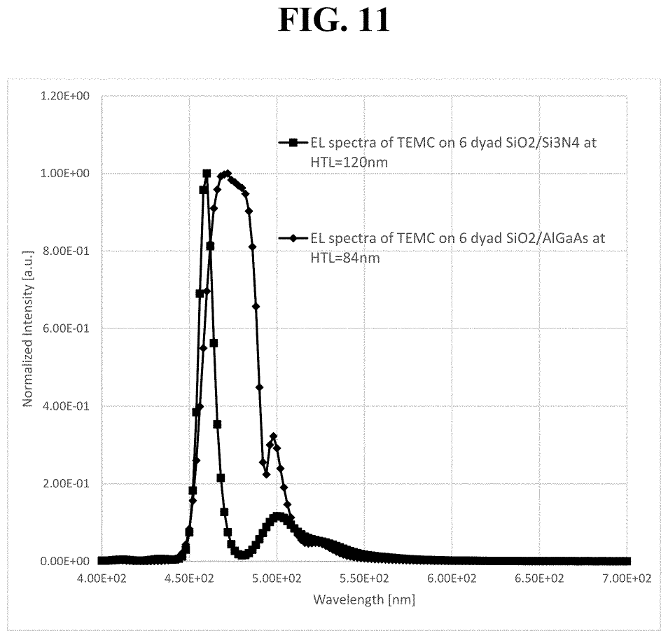

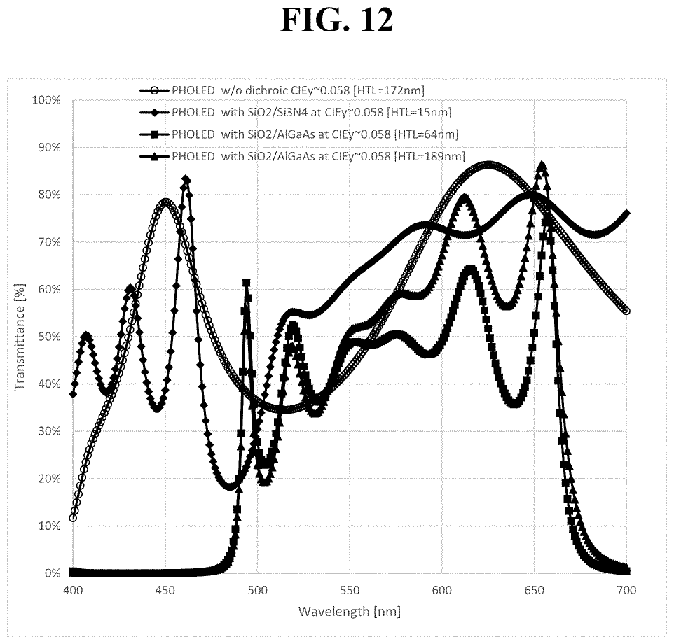

FIG. 11 shows simulated TEMC EL spectra at 1931 CIEy˜0.12 on SiO₂/Si₃N₄ and SiO₂/AlGaAs with a dichroic stack as blue light reflector.

TABLE 2

| HTL/CPL thickness | | 1931 | | | | |
|---|---|---|---|---|---|---|
| [Top/Bottom | Dichroic | CIE | T % at | T % at | LE* | LE/1931 |
| Ag = 10 nm] | Stack | x, y | 535 nm | 625 nm | [cd/A] | CIEy |
| HTL = 80 nm; | none | 0.123, | 49% | 36% | 9.4 | 78 |
| CPL = 80 nm | | 0.12 | | | | |
| HTL = 120 nm; | SiO2/Si3N4/Glass | 0.143, | 85% | 57% | 8.34 | 70 |
| CPL = 60 nm | [135 nm @6 dyads] | 0.12 | | | | |
| HTL = 84 nm; | SiO2/AlGaAs/Glass | 0.116, | 47% | 53% | 18.6 | 155 |
| CPL = 60 nm | [88 nm @6 dyads] | 0.12 | | | | |

Table 2 shows simulated 1931 CIEx,y transmittance at 535 nm, 625 nm, luminance efficacy and LE/1931 CIEy. * LE [cd/A] is optically simulated without considering triplet emission efficiency for a simplified comparison of blue PHOLED devices with and without a dichroic stack. The simulated TEMC performance target is at 1931 CIEx˜0.12.

That is, Table 1 above shows the device efficiency of semi-transparent blue OLED with dichroic and without dichroic filters at 1931 CIEy˜0.055-0.058. Compared with the low efficiency of a semi-transparent blue OLED, the device efficiency of an OLED with a dichroic stack may increase to 3.9 cd/A from 3.6 cd/A, while LE/1931 CIEy increase from 62 to 67. In the case of device with a dichroic stack using AlGaAs, the luminance efficacy increases to 15.3 cd/A and 12.7 cd/A with a different cavity design (HTL thickness=64 nm, 189 nm), respectively. The LE/1931 CIEy of device with SiO₂/AlGaAs increases from 62 (no dichroic stack) to 278 and 232 respectively. The color saturation may also increase.

Table 2 shows the device efficiency of semi-transparent blue OLED with a dichroic filter and without a dichroic filter at 1931 CIEy˜0.12. Although the luminance efficacy of device with SiO₂/Si₃N₄ may not increase, the transmittance rate for green light and red light may increase from 49% (no dichroic filter) to 85% (with dichroic filter) at 535 nm, and 36% (no dichroic filter) to 57% (with dichroic filter) at 625 nm, respectively. In real applications, high brightness from green light and red light may be realized with improved transmittance, as the power consumption may be reduced. In the case of SiO₂/AlGaAs, the luminance efficacy may increase almost two times (2×) when compared with no dichroic stack, while the LE/1931 CIEy may increases from 78 (no dichroic filter) to 155 (with dichroic filter). The two examples of weak blue emissive cavity devices with dichroic filters shows that the embodiments of the disclosed subject matter may benefit from blue light saturation with higher luminance efficacy while increasing transmittance of green light and red light, which may reduce the power consumption of devices.

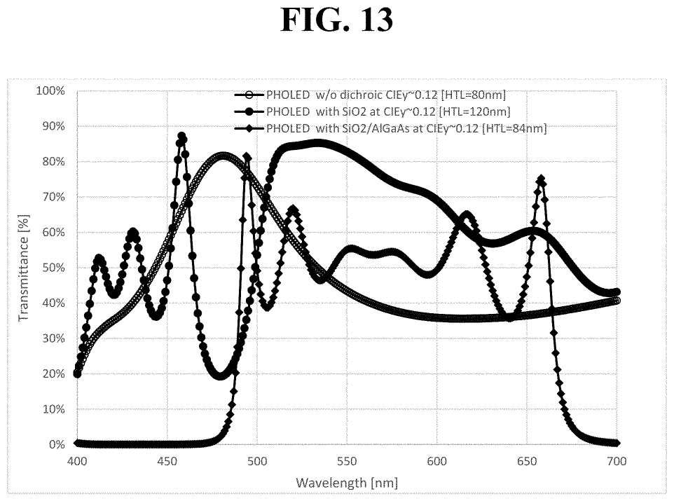

FIG. 11 shows simulated spectra of top emitting devices with a dichroic stack at 1931 CIEy=0.12. The transmittance spectra of blue OLED device with a dichroic stack are shown in FIG. 12 and FIG. 13 for 1931 CIEy at 0.058 and 0.12, respectively. In the SiO₂/AlGaAs case, two cavity parameters may deliver both saturated blue emission (1931 CIEy=0.055) with high luminance efficacy as shown in Table 1.

TABLE 3

| Device Stack [Top/Bottom | Dichroic | 1931 CIE | T % at | T % at | LE* | LE/1931 |
|---|---|---|---|---|---|---|
| Ag = 10 nm] | Stack | x, y | 535 nm | 625 nm | [cd/A] | CIEy |
| HTL = 172 nm; | none | 0.142, | 38% | 86% | 3.61 | 62 |
| CPL = 80 nm | | 0.058 | | | | |
| HTL = 15 nm; | SiO₂/Si₃N₄/Glass | 0.140, | 56% | 74% | 3.90 | 67 |
| CPL = 60 nm | [135 nm @6 dyads] | 0.058 | | | | |
| HTL = 15 nm; | SiO₂/Si₃N₄/Glass | 0.137, | 56% | 74% | 4.66 | 80 |
| CPL = 60 nm | [135 nm @10 dyads] | 0.058 | | | | |
| HTL = 80 nm; | none | 0.123, | 49% | 36% | 9.4 | 78 |
| CPL = 80 nm | | 0.12 | | | | |
| HTL = 120 nm; | SiO₂/Si₃N₄/Glass | 0.143, | 85% | 57% | 8.34 | 70 |
| CPL = 60 nm | [135 nm @6 dyads] | 0.12 | | | | |
| HTL = 111 nm; | SiO₂/Si₃N₄/Glass | 0.138, | 83% | 53% | 10.7 | 89 |
| CPL = 60 nm | [135 nm @10 dyads] | 0.12 | | | | |

Table 3 shows simulated 1931 CIE x,y, transmittance at 535 nm, 625 nm, luminance efficacy and LE/1931 CIEy for performance comparison between 6 dyads versus 10 dyads of SiO₂/Si₃N₄. * LE [cd/A] may be optically simulated without considering triplet emission efficiency versus fluorescent emitter.

Table 3 shows improvement of the luminance efficacy, transmittance, and LE/1931 CIEy by increasing the dichroic stack dyad from 6 dyads to 10 dyads. The luminance efficacy may increase from 3.9 cd/A to 4.66 cd/A by increasing the SiO₂/Si₃N₄ stack from 6 dyads to 10 dyads. Similar conclusions can be made for a device that emits color light at 1931 CIEy=0.12. That is, the luminance efficacy may increase from 8.34 cd/A to 10.7 cd/A by increasing SiO₂/Si₃N₄ stack from 6 dyads to 10 dyads.

Embodiments of the disclosed subject matter may improve the color purity of the blue light emission. In one embodiment, a weak emissive cavity with blue emission may be used to remove lower energy “greenish” light from the blue spectrum. A normal angle of incidence may be used, with no off-angle considerations. In another embodiment, cavity could be implemented by a weak dichroic filter patterned under the blue OLED patterned on the second emissive surface glass lid, to reflect blue and transmit red and green, as a low pass filter.

In another embodiment, a fill-factor of the blue sub-pixel on the blue emissive surface may be reduced to improve transmission of the blue emissive surface. Light from the silicon substrate may pass through transparent regions in blue emissive surface. A semi-reflective or reflective anode and/or cathode may be for the blue OLEDs or other emissive devices.

Embodiments of the disclosed subject matter may provide an efficient drive system for the blue emissive surface. In one embodiment, TFTs (e.g., short channel TFTs) may drive AMOLED for a blue emissive surface. In another embodiment, a passive matrix or 1 TFT (to avoid cathode patterning) may be used to drive OLEDs in the blue emissive surface as four separate displays from all sides to reduce multiplexing of the passive matrix. In another embodiment, a silicon backplane may be transferred from a silicon wafer.

In an embodiment of the disclosed subject matter, green and red light emissive devices may be patterned on silicon.

The substrate may have unpatterned red emissive device with patterned green emissive device with three color filters. The color filters may be yellow, green, and red color filters. The alignment tolerance for green emissive devices may be reduced, as red color filters may remove green light from the red emitted light. Correction with software and/or hardware may compensate for spatial variations across an array of emissive devices.

In an embodiment of the disclosed subject matter, a dichroic filter may be used to reflect blue light (e.g., to make a blue upper emissive layer a cavity) but may pass and/or transmit green, yellow and/or red light from a lower emissive surface and/or plane. In this arrangement, a weak blue reflection of light may be used.

In an embodiment of the disclosed subject matter, a display may be configured to have a resolution that is greater than a predetermined resolution and a brightness that is greater than a predetermined brightness.

In another embodiment of the disclosed subject matter, micro-OLEDs may be used for the plurality of emissive surfaces, or may be organic light emitting devices (OLEDs), light emitting devices (LEDs), perovskite LEDs, micro-LEDs, and/or quantum dots.

In embodiments of the disclosed subject matter, a display device may have a lifetime that is greater than a predetermined lifetime and an efficiency that is greater than a predetermined efficiency.

In another embodiment of the disclosed subject matter, deep blue may not be needed for AR (augmented reality) devices, so a non-cavity blue emissive layer may be used.

In yet another embodiment of the disclosed subject matter, a top emission yellow AMOLED plane disposed on silicon may be used to eliminate OLED patterning. Color filters may be used in this arrangement to output red light and green light.

In an embodiment of the disclosed subject matter, a transparent blue OLED may be disposed on glass to form a blue emissive surface, which may be used as a lid for a silicon backplane and/or OLED. The refractive index of upper RG(Y) emissive surface may be matched with the substrate of the blue emissive surface.

In another embodiment of the disclosed subject matter, a blue OLED disposed on a glass substrate of one emissive surface and/or plane may be 1/16 resolution of a yellow OLED of another emissive surface and/or plane.

In yet an embodiment of the disclosed subject matter, the blue OLED may be driven as AMOLED. If the TFTs of the drive system occupy greater than a predetermined amount of space for a particular device, a PMOLED may be used, along with cathode separators. Alternatively, a PMOLED with one TFT per pixel may be used, which may avoid having to pattern the cathode of the blue emissive surface.

In an embodiment of the disclosed subject matter, an OLED microdisplay containing two emissive surfaces each with independent scan and data drive systems, where an image formed may be the combination of light from the two substrates.

Embodiments of the disclosed subject matter may include an emissive surface that is configured to emit blue light, and another emissive surface that is configured to emit green light and red light. In some embodiments of the disclosed subject matter, one emissive surface may be configured to emit blue light. Another emissive surface may be configured to emit yellow light. Color altering media may be used to form green light and red light from the emitted yellow light.

In some embodiments, blue pixels of an emissive surface may have a lower resolution than other pixels that emit light of other colors. The blue pixels of the emissive surface may be driven by a passive matrix. Yellow pixels or green and red pixels of another emissive surface may be driven by active matrix.

In some embodiments of the disclosed subject matter, a passive matrix may drive an upper emitting surface. The passive matrix may be configured to have one (1) TFT per sub-pixel. This arrangement may avoid having to pattern the cathodes of the pixels.

In embodiments of the disclosed subject matter, a blue emissive surface disposed on a substrate may be transparent. A blue stack of the emissive surface may have microcavity configured to emit blue light.

In an embodiment of the disclosed subject matter, a dichroic filter may be disposed between blue pixels and yellow or green and red pixels to allow yellow or green and red light to pass through, while reflecting blue light.

In another embodiment of the disclosed subject matter, a backplane for top emitting surface may be transferred from a growth substrate.

In yet another embodiment of the disclosed subject matter, an emissive surface may be driven by both a passive matrix and an active matrix, with each disposed in a different region of the emissive surface.

FIGS. 1-3 and 5-13 as described above show example embodiments of the disclosed subject matter. A device, such as shown in FIGS. 3, 5, and 9 may include a display having a plurality of emissive surfaces, where each of the plurality of emissive surfaces has emissive devices that are deposited or attached in the same plane. Each of the plurality of emissive surfaces may be configured with independent scan and data drivers (e.g., active matrix drivers, passive matrix drivers, or the like). The display may be configured to display an image that is a combination of light from the plurality of emissive surfaces. Each of the plurality of emissive surfaces may render an image that differs by color resolution, fill-factor, viewing angle, and/or transparency.

The display of the device may be a microdisplay that has a diagonal measurement that is less than or equal to three (3) inches, less than or equal to two (2) inches, less than or equal to one (1) inch, or the like. The display may be a microdisplay has a resolution that is greater than or equal to 1000 dots per inch (DPI) or 1000 pixels per inch (PPI), greater than or equal to 1500 DPI or 1500 PPI, greater than or equal to 2000 DPI or 2000 PPI, greater than or equal to 3000 DPI or 3000 PPI, or the like.

In the embodiments described throughout, the display of the device may be an organic light emitting device (OLED) display, a micro-OLED display, a light emitting device (LED) display, a micro-LED display, a quantum dot display, a quantum dot LED display, and a perovskite LED display. The emissive devices of the display may be organic light emitting devices (OLEDs), light emitting devices (LEDs), perovskite LEDs, micro-LEDs, micro-OLEDs, and/or quantum dots.

As shown in FIG. 2, a first emissive surface of the plurality of emissive surface of the device may be configured to emit blue light, and a second emissive surface of the plurality of emissive surfaces may be configured to emit green light and red light. The first emissive surface may be disposed on a transparent substrate, and the first emissive surface may include a plurality of planes of emissive materials that are stacked vertically and are configured to emit the blue light. The stacked arrangement of emissive materials may include at least one microcavity configured to emit the blue light. The devices of the stacked arrangement may include organic light emitting devices (OLEDs), light emitting devices (LEDs), perovskite LEDs, micro-LEDs, micro-OLEDs, and/or quantum dots.

A first emissive surface of the plurality of emissive surface of the device may be configured to emit blue light, and a second emissive surface of the plurality of emissive surfaces may be configured to emit yellow light. The display of the device may include color altering media configured to output green light or red light based on the blue light emitted from the first emissive surface, and/or the yellow light emitted from the second emissive surface.

The plurality of emissive surfaces of the device may include a plurality of pixels, where one or more pixels of the plurality of pixels that are configured to emit blue light have a lower resolution than other pixels of the plurality of pixels.

The plurality of emissive surfaces may include a plurality of pixels, and the device may include a passive matrix drive system (e.g., as shown in FIG. 2) that is configured to drive at least one of the plurality of pixels that is configured to emit blue light. The device may include a first active matrix drive system that is configured to drive one or more pixels of the plurality of pixels that are configured to emit yellow light, one or more pixels of the plurality of pixels that are configured to emit green light, and/or one or more pixels of the plurality of pixels that are configured to emit red light. The device may include a second active matrix drive system that is configured to drive a portion of the plurality of pixels that are configured to emit blue light. The second active matrix drive system may drive the portion of the plurality of pixels in a different region than the passive matrix drive system. The passive matrix drive system of the device may include a thin film transistor (TFT) per pixel of a plurality of sub-pixels that are configured to emit blue light. One of the plurality of emissive surfaces of the device may include a backplane from a growth substrate.

As shown in FIG. 2, the plurality of emissive surfaces of device may include a first emissive surface having a plurality of pixels configured to emit blue light. A second emissive surface may include a plurality of pixels configured to emit yellow light, green light, and/or red light. The device may include a dichroic filter disposed between the first emissive surface and the second emissive surface configured to pass the yellow light, the green light, and/or red light through the dichroic filter, and/or be configured to reflect the blue light.

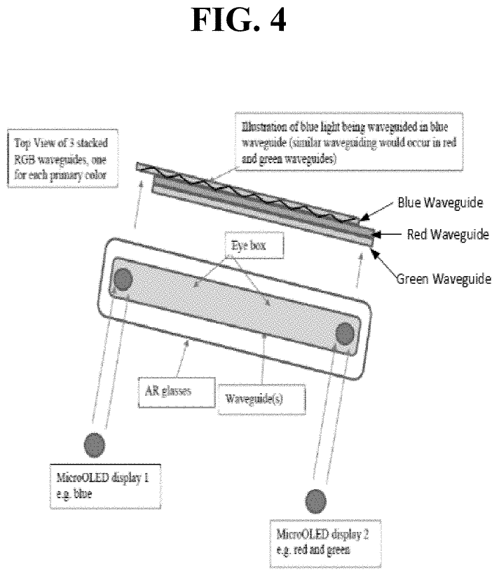

FIG. 4 shows an example embodiment of the disclosed subject matter where a stack of red, green, and blue (RGB) waveguides may be integrated into a set of AR glasses, where there may be one waveguide for each color. Colors of light may be combined in each waveguide to reduce the number of waveguides (e.g., from three waveguides to two waveguides). Light from each microdisplay may enter one side of the waveguide and may travel through the waveguide to the regions (e.g., the eyebox shown in FIG. 4) where the light may be refracted back to the eye of the user. The light may be separated into two separate projectors, one for blue light and one for red, green, and yellow (RGY) light. In this arrangement, no pixel level patterning may be needed for the displays (e.g., micro-OLED displays), and a fill-factor for the sub-pixels of the emissive surfaces of the displays may be increased, which may increase display brightness and lifetime. Although the use of two displays may increase the cost of a device, each display may be simpler to fabricate without high-resolution pixel-level organic patterning and may increase the performance of the device. An input video image may be separated into component colors (e.g., red, green, and blue) and video information and/or data may be provided to each display (e.g., microdisplay) so that the resultant final image is the combination of images from the two microdisplays.

The displays of the two-display arrangement may be micro-LED displays, micro-OLED displays, or other displays, as described throughout. Presently, it is typically difficult to make high efficiency full-color high resolution micro-LED displays. Growing RGB devices on the same substrate or transferring RGB devices grown on another substrate is typically very challenging for high resolution microdisplays. If a monochrome blue micro-LED display is fabricated, quantum dots typically may not be used for down conversion, as their printing processes do not allow for very high resolutions (e.g., resolutions that are greater than a predetermined resolution). Moreover, red and green micro-LEDs are typically inefficient.

Using the two-display arrangement of the disclosed subject matter, with one display emitting blue (B) light and the other display emitting red and green (RG) light, RG micro-LEDs may be made by depositing an unpatterned mixture of RG quantum dots over blue micro-LEDs. There may be a mixture of red and green downconversion quantum dots in one layer. Or, two stacked layers of quantum dots may be used, with one thin so that approximately 50% blue light passes through first layer (i.e., the red layer) to second layer (green). Lithography may be used to pattern color filters. Blue light may be absorbed by both quantum dot layers, and the display may produce yellow light which is filtered into red and green sub-pixels by the color filters.

Alignment may be performed electronically using spare pixels at a periphery of the display. Both displays (e.g., microdisplays) may be aligned to the waveguide or waveguides so that a user is able to view the combination of colors for the same image produced by both displays for a full-color image. If each display has additional pixels (e.g., 1000×800) when producing an image having less pixels (e.g., 800×640 pixels), then a system controller and/or processor communicatively coupled to the display devices may move the 800×640 pixel image within the display to align it with a position on the waveguide to yield a full color image. A camera may be used to view the resultant image, and the controller may move the images in each display so the resultant image has one full color pixel which combines the individual blue and red/green pixels from the two different displays.

In one embodiment, an AR, VR, or MR system may include two displayed (e.g., microdisplays), with each providing light of a different color spectrum, and one or more waveguides through which light from the microdisplays may be combined and viewed by a user. A blue display (e.g., microdisplay) may have a lower resolution than a red/green display (e.g., microdisplay). The displays may be micro-OLED or micro-LED.

According to an embodiment, such as shown in FIG. 4, a device may include an augmented reality (AR), virtual reality (VR), or mixed reality (MR) system having a plurality of displays, with each of the plurality of displays rendering an image based on the provided light of a different color spectrum. The device may include one or more waveguides through which light from the plurality of displays is combined and configured to be viewable by a user. For example, FIG. 4 shows a first waveguide configured to guide blue light, a second waveguide configured to guide green light, and/or a third waveguide configured to guide red light.

Each of the plurality of displays of the device, such as shown in FIG. 4, may be a microdisplay that has a diagonal measurement that is less than or equal to three (3) inches, less than or equal to two (2) inches, less than or equal to one (1) inch, or the like. Each of the plurality of displays of the device may be a microdisplay that has a resolution that is greater than 1000 dots per inch (DPI) or 1000 pixels per inch (PPI), greater than or equal to 1500 DPI or 1500 PPI, greater than or equal to 2000 DPI or 2000 PPI, greater than or equal to 3000 DPI or 3000 PPI, or the like. Although FIG. 4 shows micro-OLED displays, the display of the device may be an organic light emitting device (OLED) display, a micro-OLED display, a light emitting device (LED) display, a micro-LED display, a quantum dot display, a quantum dot LED display, and/or a perovskite LED display.

The plurality of displays of the device may include a first display configured to emit blue light, and a second display configured to emit red light and green light (e.g., as shown in FIG. 4). The first display of the device may have a lower resolution that the second display. The second display may include an unpatterned mixture of quantum dots, OLEDs, micro-LEDs, and/or perovskite LEDs configured to emit red or green light that are disposed over a micro light emitting device (micro-LED), quantum dot LEDs, perovskite LEDs, and/or a micro organic light emitting device (micro-OLED) of the first display that may be configured to emit blue light. The second display may include a first layer configured to emit red light to a second layer to emit green light. The first layer and the second layer may have different thicknesses and may be stacked on the first display.

In some embodiments, the plurality of displays of the device may include a first display configured to emit blue light, a plurality quantum dots configured to absorb the emitted blue light and output yellow light, and/or a plurality of filters configured to convert the yellow light into red light and green light.

A consumer product may include the devices described above in connection with FIGS. 3-13, and may be a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display less than 3 inches diagonal, a 3-D display, a virtual reality or augmented reality display, a vehicle, a video wall comprising multiple displays tiled together, a theater or stadium screen, and a sign.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
a display comprising a plurality of emissive surfaces, wherein each of the plurality of emissive surfaces has emissive devices that are deposited or attached in the same plane, with each of the plurality of emissive surfaces configured with independent scan and data drivers, and wherein the display is configured to display an image that is a combination of light from the plurality of emissive surfaces, wherein each of the plurality of emissive surfaces renders an image that differs by at least one selected from the group consisting of: color resolution, fill-factor, viewing angle, and transparency.

2. The device of claim 1, wherein the display is a microdisplay that has a diagonal measurement that is less than or equal to three inches.

3. The device of claim 1, wherein the display is a microdisplay has a resolution that is greater than 1000 dots per inch (DPI) or 1000 pixels per inch (PPI).

4. The device of claim 1, wherein the display comprises at least one selected from the group consisting of: an organic light emitting device (OLED) display, a micro-OLED display, a light emitting device (LED) display, a micro-LED display, a quantum dot display, a quantum dot LED display, and a perovskite LED display.

5. The device of claim 1, wherein the emissive devices comprise at least one selected from the group consisting of: organic light emitting devices (OLEDs), light emitting devices (LEDs), perovskite LEDs, micro-LEDs, micro-OLEDs, and quantum dots.

6. The device of claim 1, wherein a first emissive surface of the plurality of emissive surface is configured to emit blue light, and a second emissive surface of the plurality of emissive surfaces are configured to emit green light and red light.

7. The device of claim 6, wherein the first emissive surface is disposed on a transparent substrate, and
wherein the first emissive surface comprises a plurality of planes of emissive materials that are stacked vertically and are configured to emit the blue light.

8. The device of claim 7, wherein the stacked arrangement of emissive materials comprises at least one microcavity configured to emit the blue light.

9. (canceled)

10. The device of claim 1, wherein a first emissive surface of the plurality of emissive surface is configured to emit blue light, and a second emissive surface of the plurality of emissive surfaces is configured to emit yellow light, and
wherein the display includes color altering media configured to output green light or red light based on at least one selected from the group consisting of: the blue light emitted from the first emissive surface, and the yellow light emitted from the second emissive surface.

11. (canceled)

12. The device of claim 1, wherein the plurality of emissive surfaces comprises a plurality of pixels, and the device further comprises:
a passive matrix drive system that is configured to drive at least one of the plurality of pixels that is configured to emit blue light; and
a first active matrix drive system that is configured to drive one or more of the pixels selected from the group consisting of: one or more pixels of the plurality of pixels that are configured to emit yellow light, one or more pixels of the plurality of pixels that are configured to emit green light, and one or more pixels of the plurality of pixels that are configured to emit red light.

13. The device of claim 12, further comprising:
a second active matrix drive system that is configured to drive a portion of the plurality of pixels that are configured to emit blue light,
wherein the second active matrix drive system drives the portion of the plurality of pixels in a different region than the passive matrix drive system.

14. (canceled)

15. The device of claim 1, wherein the plurality of emissive surfaces comprises:
a first emissive surface comprising a plurality of pixels configured to emit blue light;
a second emissive surface comprising a plurality of pixels configured to emit at least one selected from the group consisting of: yellow light, green light, and red light;
a dichroic filter disposed between the first emissive surface and the second emissive surface configured to pass the at least one selected from the group consisting of: the yellow light, the green light, and red light through the dichroic filter, and configured to reflect the blue light.

16. (canceled)

17. A device comprising:
an augmented reality (AR), virtual reality (VR), or mixed reality (MR) system comprising a plurality of displays, with each of the plurality of displays rendering an image based on the provided light of a different color spectrum; and
one or more waveguides through which light from the plurality of displays is combined and configured to be viewable by a user.

18. (canceled)

19. (canceled)

20. The device of claim 17, wherein the display comprises at least one selected from the group consisting of: an organic light emitting device (OLED) display, a micro-OLED display, a light emitting device (LED) display, a micro-LED display, a quantum dot display, a quantum dot LED display, and a perovskite LED display.

21. The device of claim 17, wherein the plurality of displays comprise:
a first display configured to emit blue light; and
a second display configured to emit red light and green light.

22. (canceled)

23. The device of claim 21, wherein the second display comprises an unpatterned mixture of at least one selected from the group consisting of: quantum dots, OLEDs, micro-LEDs, and perovskite LEDs configured to emit red or green light that are disposed over at least one selected from the group consisting of: a micro light emitting device (micro-LED), quantum dot LEDs, perovskite LEDs, or a micro organic light emitting device (micro-OLED) of the first display that is configured to emit blue light.

24. The device of claim 21, wherein the second display comprises a first layer configured to emit red light to a second layer to emit green light, and
wherein the first layer and the second layer have different thicknesses and are stacked on the first display.

25. The device of claim 17, wherein the plurality of displays comprise:
a first display configured to emit blue light;
a plurality quantum dots configured to absorb the emitted blue light and output yellow light; and
a plurality of filters configured to convert the yellow light into red light and green light.

26. (canceled)

27. A consumer product comprising the device recited in claim 1, wherein the device comprises a type selected from a group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display less than 3 inches diagonal, a 3-D display, a virtual reality or augmented reality display, a vehicle, a video wall comprising multiple displays tiled together, a theater or stadium screen, and a sign.

28. The device of claim 17, wherein the device comprises a type selected from a group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display less than 3 inches diagonal, a 3-D display, a virtual reality or augmented reality display, a vehicle, a video wall comprising multiple displays tiled together, a theater or stadium screen, and a sign.
